(19) United States
(12) Patent Application Publication
(10) Pub. No.: US 2025/0336666 A1
(43) Pub. Date: Oct. 30, 2025

(54) METHODS AND ASSEMBLIES FOR MODIFYING A SURFACE

(71) Applicant: ASM IP Holding B.V., Almere (NL)

(72) Inventors: Adriaan Jacobus Martinus Mackus, Son en Breugel (NL); Johanna Henrica Deijkers, Best (NL); Nicholas John Chittock, Warwick (GB); Wilhelmus M.M. Kessels, Tilburg (NL)

(21) Appl. No.: 19/186,151

(22) Filed: Apr. 22, 2025

Related U.S. Application Data
(60) Provisional application No. 63/639,357, filed on Apr. 26, 2024.

(51) Int. Cl. H01L 21/02

(52) U.S. Cl. CPC H01L 21/02252; H01L 21/02065; H01L 21/02172; H01L 21/02244

(57) ABSTRACT

The disclosure relates to methods and assemblies for processing semiconductor substrates, such as methods and assemblies for removing, such as etching, a molybdenum-comprising material from a semiconductor substrate. The methods may be useful in manufacturing semiconductor devices, such as memory devices, transistors and diodes. The methods of removing molybdenum-comprising material from a surface of a substrate disclosed herein comprise providing a substrate comprising molybdenum-comprising material in a reaction chamber, providing a halogen-comprising plasma in the reaction chamber to halogenate the molybdenum-comprising material, and providing an oxygen reactant into the reaction chamber to form a volatile molybdenum compound. In some embodiments, the halogen-comprising plasma further comprises sulfur. In particular, the disclosure relates to methods of removing oxidized material from an elemental molybdenum layer and to methods of thinning a molybdenum nitride layer.

### CROSS-REFERENCE TO RELATED APPLICATION(S)

This application claims the benefit of U.S. Provisional Application 63/639,357 filed on Apr. 26, 2024, the entire contents of which are incorporated herein by reference.

### FIELD

The present disclosure generally relates to methods and assemblies for processing semiconductor substrates. M ore particularly, the disclosure relates to methods and assemblies for removing a particular material on a semiconductor substrate.

### BACKGROUND

Molybdenum-comprising materials, such as molybdenum disulfide (MoS₂), molybdenum oxide (MoOₓ), molybdenum nitride (MoNₓ), molybdenum carbide (MoCₓ) and metallic molybdenum (Mo) are intensively studied for their advantageous properties in electronic device manufacturing. Particularly, MoS₂ is a two-dimensional (2D) transition metal dichalcogenide (TMD) with applications in catalysis and nanoelectronics. Direct deposition of a material to produce a 2D material is challenging in terms of layer continuity and surface structure. Thus, to enable integration of 2D materials in nanoelectronics, processes containing etching steps are of interest to the industry, in particular, highly controlled and low-damage etching processes are sought after.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of removing a particular material from the surface of a substrate, such as a silicon substrate used for fabricating semiconductor devices. Embodiments of the current disclosure further relate to methods of fabricating semiconductor devices, and to semiconductor processing assemblies.

In one aspect, a method of removing molybdenum-comprising material from a surface of a substrate is disclosed. The method comprises providing a substrate comprising molybdenum-comprising material in a reaction chamber, providing a halogen-comprising plasma in the reaction chamber to halogenate the molybdenum-comprising material, and providing an oxygen reactant into the reaction chamber to form a volatile molybdenum compound. In some embodiments, the halogen-comprising plasma further comprises sulfur. In some embodiments, the oxygen reactant is an oxygen-comprising plasma. In some embodiments, the oxygen reactant is an oxygen-comprising plasma generated from a gas comprising an oxygen source selected from a group consisting of CO₂, N₂O, H₂O, O₃ and O₂. In some embodiments, the oxygen reactant is plasma generated from a gas comprising O₂. In some embodiments, the oxygen reactant is plasma generated from a gas comprising O₂ as the only oxygen source. In some embodiments, the oxygen reactant is plasma generated from a gas consisting essentially of, or consisting of, O₂. In some embodiments, the oxygen reactant is a gas comprising O₃ as the only oxygen source.

In some embodiments, the halogen-comprising plasma and the oxygen reactant are provided into the reaction chamber alternately and sequentially.

In some embodiments, the molybdenum-comprising material is selected from a group consisting of molybdenum dichalcogenides, molybdenum nitride, molybdenum oxide, molybdenum carbide, metallic molybdenum and combinations thereof.

In some embodiments, the molybdenum-comprising material is selected from a group consisting of MoS₂, MoSe₂ and combinations thereof.

In some embodiments, the halogen-comprising plasma is generated from a gas comprising SF₆.

In some embodiments, the halogen-comprising plasma is generated from a gas comprising molecular hydrogen (H₂).

In some embodiments, the flow rate ratio of SF₆ to the combination of SF₆ and H₂ is below 0.9.

In some embodiments, the oxygen reactant is an oxygen-comprising plasma. In some embodiments, the oxygen-comprising plasma is generated from a gas comprising O₂. In some embodiments, the oxygen reactant is an oxygen-comprising plasma generated from a gas comprising an oxygen source selected from a group consisting of CO₂, N₂O, H₂O and O₂.

In some embodiments, the method is a cyclic material removal method, and providing the halogen-comprising plasma in the reaction chamber and providing an oxygen reactant into the reaction chamber form a material removal cycle.

In some embodiments, the material removal cycle is performed at least twice.

In some embodiments, the removal rate of the molybdenum-comprising material is less than about 1.2 Å/cycle.

In some embodiments, the halogen-comprising plasma is provided into the reaction chamber from about 0.1 seconds to about 20 seconds.

In some embodiments, the oxygen reactant is provided into the reaction chamber from about 0.1 seconds to about 20 seconds.

In some embodiments, the removal of molybdenum-comprising material is substantially self-limiting.

In one aspect, a method of cleaning a surface is disclosed. The method of cleaning a surface comprises providing a surface having molybdenum-comprising material thereon, contacting the surface with a halogen-comprising plasma to halogenate the molybdenum-comprising material, and contacting the surface with an oxygen reactant to form a volatile molybdenum compound. The method of cleaning a surface according to the current disclosure can be used to remove molybdenum-comprising material from a surface. The surface from which the molybdenum-comprising material is removed may be a molybdenum-comprising material—the same that is being removed or a different one—or a different material.

In another aspect, a method of removing oxidized material from an elemental molybdenum layer is disclosed. The method comprises providing an elemental molybdenum layer having oxidized material thereon, contacting the elemental molybdenum layer with a halogen-comprising plasma to halogenate the oxidized material, and contacting the elemental molybdenum layer with an oxygen reactant to form a volatile molybdenum compound.

In some embodiments, the method of removing oxidized material is performed in a reaction chamber.

In yet another aspect, a method of thinning a molybdenum nitride layer is disclosed. The method comprises providing a substrate comprising a molybdenum nitride layer in a reaction chamber, providing a halogen-comprising plasma in the reaction chamber to halogenate the molybdenum nitride layer, and providing an oxygen reactant into the reaction chamber to form a volatile molybdenum compound. The method of thinning a molybdenum nitride layer may be applied in other molybdenum-comprising materials, such as molybdenum carbide, molybdenum dichalcogenides (such as MoS₂, MoSe₂) and molybdenum oxide.

In further aspect, a work function layer consisting essentially of molybdenum nitride formed by a method according to the current disclosure is disclosed.

In an additional aspect, a semiconductor processing assembly is disclosed. The semiconductor processing assembly comprises a reaction chamber constructed and arranged to hold a substrate comprising a molybdenum-comprising layer and an injector system constructed and arranged to provide a halogen-comprising plasma and an oxygen reactant into the reaction chamber. The semiconductor processing assembly further comprises a halogen reactant source constructed and arranged to contain a halogen reactant for generating a halogen-comprising plasma and an oxygen reactant source constructed and arranged to contain an oxygen reactant for generating the oxygen reactant. The semiconductor processing assembly is constructed and arranged to provide the halogen-comprising plasma and the oxygen reactant via the injector system into the reaction chamber to remove molybdenum-comprising material from the substrate.

In some embodiments of the semiconductor processing assembly, the injector system comprises a plasma generator located upstream of the reaction chamber.

In some embodiments of the semiconductor processing assembly, the injector system comprises a plasma generator for generating plasma in the reaction chamber.

In some embodiments of the semiconductor processing assembly, the assembly comprises a controller configured to cause the semiconductor processing assembly to provide the halogen-comprising plasma and the oxygen reactant alternately and sequentially into the reaction chamber.

In a yet further aspect, a semiconductor processing assembly constructed and arranged to perform a method according to the current disclosure is disclosed.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

FIG. 1 is a block diagram of exemplary embodiments of a method according to the current disclosure.

FIG. 2 is a schematic presentation of exemplary embodiments of a method according to the current disclosure.

FIG. 3 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

In one aspect, a method of removing molybdenum-comprising material from a surface of a substrate is disclosed. The method comprises providing a substrate comprising molybdenum-comprising material in a reaction chamber, providing a halogen-comprising plasma in the reaction chamber to halogenate the molybdenum-comprising material, and providing an oxygen reactant into the reaction chamber to form a volatile molybdenum compound. In some embodiments, oxygen reactant is provided in a vapor phase. In some embodiments, oxygen reactant is provided in or as a plasma.

The method of removing molybdenum-comprising material according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

In some embodiments, the substrate may be pretreated or cleaned prior to or at the beginning of the method according to the current disclosure. In some embodiments, the substrate may be subjected to a plasma cleaning process prior to or at the beginning of the current method. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the current method. In some embodiments, the substrate surface may be exposed to hydrogen plasma, radicals, or atomic species prior to or at the beginning of the current method. In some embodiments, a pretreatment or cleaning process may be carried out in the same reaction chamber as the current method. However, in some embodiments, a pretreatment or cleaning process may be carried out in a separate reaction chamber.

The substrate according to the current disclosure comprises molybdenum-comprising material. In some embodiments, the molybdenum-comprising material forms a layer. As used herein, the term “layer” and/or “film” can refer to any continuous or non-continuous material. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer is closed. In some embodiments, the molybdenum-comprising material is deposited on the substrate. The molybdenum-comprising material may be a part of a partially fabricated semiconductor device.

In some embodiments, the molybdenum-comprising material is selected from a group consisting of molybdenum dichalcogenides, molybdenum nitride, molybdenum oxide, molybdenum carbide, metallic molybdenum and combinations thereof. In some embodiments, the molybdenum-comprising material is selected from a group consisting of MoS₂, MoSe₂ and combinations thereof. In some embodiments, the molybdenum-comprising material is MoS₂. In some embodiments, the molybdenum-comprising material is MoSe₂. In some embodiments, the molybdenum-comprising material is molybdenum oxide. Molybdenum oxide may be, for example MoO₂ or MoO₃. In some embodiments, the molybdenum-comprising material is molybdenum nitride. Molybdenum nitride may be, for example, Mo₂N or MoN. In some embodiments, the molybdenum-comprising material is molybdenum carbide (MoCₓ), including MoC and Mo₂C. In some embodiments, the molybdenum-comprising material is metallic, i.e. elemental, molybdenum. In some embodiments, the molybdenum-comprising material is metallic molybdenum having surface oxidation. By an elemental molybdenum is herein meant molybdenum having an oxidation state of 0.

The methods described herein may be used in the manufacture of, for example, logic devices, memory devices and sensors. M ore particularly, the current methods may be used in the manufacture of a transistor, an interconnect, a memory cell or a diode. In some embodiments, a partially fabricated semiconductor device comprising the molybdenum-comprising material is a transistor. In some embodiments, the partially fabricated semiconductor device comprising the molybdenum-comprising material is an interconnect. In some embodiments, the partially fabricated semiconductor device comprising the molybdenum-comprising material is a memory cell. In some embodiments, the partially fabricated semiconductor device comprising the molybdenum-comprising material is a diode. The molybdenum-comprising material according to the current disclosure, and the methods described herein, may be used in forming a diffusion barrier, for example, a copper diffusion barrier.

In the current disclosure, halogen-comprising plasma is used to halogenate the molybdenum-comprising material. By halogenating the molybdenum-comprising material is herein meant the attachment of halogen atoms from the sulfur and halogen-comprising plasma on the surface of the molybdenum-comprising material. The halogenation according to the current disclosure takes place to a predetermined depth of the molybdenum-comprising material. In some embodiments, only the surface of the molybdenum-comprising material is halogenated. In some embodiments, the halogen-comprising plasma is generated from a gas that contains sulfur and halogen. In some embodiments, the halogen-comprising gas comprises sulfur and fluorine. In some embodiments, the halogen-comprising plasma is generated from a gas comprising a halogen-comprising compound. In some embodiments, the halogen-comprising plasma is generated from a gas comprising a halogen and sulfur. In some embodiments, the halogen-comprising plasma is generated from a gas comprising a fluorine and sulfur. In some embodiments, the halogen-comprising plasma comprises sulfur. In some embodiments, the halogen-comprising plasma is generated from a gas comprising a compound consisting of sulfur and halogen. In some embodiments, the halogen-comprising plasma is generated from a gas comprising a sulfur and fluorine-comprising compound. In some embodiments, the halogen-comprising plasma is generated from a gas comprising SF₆. In some embodiments, the halogen-comprising plasma is generated from a gas comprising nitrogen and fluorine. In some embodiments, the halogen-comprising plasma is generated from a gas comprising NF₃. In some embodiments, the halogen-comprising plasma is generated from a gas comprising a gaseous fluorocarbon, such as CF₄. In embodiments, in which the halogen is fluorine, the substrate surface (i.e. the molybdenum-comprising material) is fluorinated. In some embodiments, the halogen-comprising plasma does substantially not contain chlorine. In some embodiments, the method according to the current disclosure is substantially chlorine-free.

Contacting the substrate with halogen-comprising plasma, i.e. the phase of providing a halogen-comprising plasma, such as a sulfur and halogen-comprising plasma, into the reaction chamber is intended not to substantially etch the molybdenum-comprising material. In some embodiments, the molybdenum-comprising material is not detectably etched during providing the halogen-comprising plasma into the reaction chamber. Therefore, the concentration of the halogen-comprising gas, such as the sulfur and halogen-comprising gas in the gas stream in which the plasma is generated is kept to a predetermined level. Also other process parameters, such as temperature and pressure of the reaction chamber, as well as the duration of providing the halogen-comprising plasma (i.e. plasma pulse time) are controlled.

In some embodiments, the halogen-comprising plasma is generated from a gas comprising molecular hydrogen (H₂). Molecular hydrogen can be used to dilute the halogen-comprising gas, and in embodiments in which the gas comprises sulfur, both sulfur and halogen. Dilution of the halogen-comprising gas may be used to dilute the halogen-comprising gas to a level on which the plasma generated from the gas has a desired halogenation effect. Without limiting the current disclosure to any specific theory, providing molecular hydrogen to the gas stream from which the halogen-comprising plasma is generated, may be beneficial also due to the scavenging activity of hydrogen reactive species. In other words, the halogenation effect of the molybdenum-comprising material may be reduced further than the dilution ratio would suggest. For example, at least some of the most reactive species in the halogen-comprising plasma may be scavenged by hydrogen, leading to a milder halogenation treatment of the molybdenum-comprising material.

In some embodiments, the removal of molybdenum-comprising material according to the current disclosure is done selectively relative to other materials. Further, it may be possible to selectively etch one or more molybdenum-comprising materials relative to other molybdenum-comprising materials. Without limiting the current disclosure to any specific theory, the selectivity of material removal may be adjusted by regulating the ratio of the halogen-comprising reactant and hydrogen in the gas stream from which the halogen-comprising plasma is generated. In some embodiments, particularly in embodiments relating to surface cleaning processes, molybdenum oxide layer on a metallic molybdenum-comprising material could be removed, while keeping the metallic molybdenum-comprising material un-etched.

In some embodiments, the halogen-comprising plasma is generated from a gas or mixture of gases that substantially does not contain hydrogen, and hydrogen is provided into the reaction chamber downstream of plasma generation. In such embodiments, the hydrogen and the plasma may be provided into the reaction chamber through the same flow path, such as an inlet.

The gas mixture used for generating halogen-comprising plasma may contain additional compounds or elements. In some embodiments, the gas mixture used for generating halogen-comprising plasma comprises at least one inert gas, such as a noble gas. A noble gas may be selected from a group consisting of helium (He), neon (Ne), argon (Ar) krypton (Kr) and xenon (Xe). In some embodiments, the gas mixture used for generating halogen-comprising plasma comprises Ar. In some embodiments, the gas mixture used for generating halogen-comprising plasma comprises Ne. In some embodiments, the gas mixture used for generating halogen-comprising plasma comprises He. In some embodiments, the gas mixture used for generating halogen-comprising plasma comprises Kr. In some embodiments, the gas mixture used for generating halogen-comprising plasma comprises Xe.

In some embodiments, the gas mixture used for generating halogen-comprising plasma comprises nitrogen. In some embodiments, the gas mixture used for generating halogen-comprising plasma comprises nitrogen and an additional inert gas.

In some embodiments, the halogen-comprising plasma is generated from a gas comprising SF₆ and H₂. In some embodiments, the flow rate ratio of SF₆ to the combination of SF₆ and H₂ is below 1. In some embodiments, the flow rate ratio of SF₆ to the combination of SF₆ and H₂ is below 0.9. In some embodiments, the flow rate ratio of SF₆ to the combination of SF₆ and H₂ is below 0.8. In some embodiments, the flow rate ratio of SF₆ to the combination of SF₆ and H₂ is below 0.5. In some embodiments, the flow rate ratio of SF₆ to the combination of SF₆ and H₂ is below 0.4. In some embodiments, the flow rate ratio of SF₆ to the combination of SF₆ and H₂ is below 0.3. In some embodiments, the flow rate ratio of SF₆ to the combination of SF₆ and H₂ is less than about 0.29 or less than about 0.28 or less than about 0.27 or less than about 0.25 or less than about 0.23 or less than about 0.2 or less than about 0.15 or less than about 0.1 or less than about 0.07 or less than about 0.05 or less than about 0.03. A flow rate ratio in the current disclosure means the mass flow rate of a first compound (such as SF₆) relative to the mass flow rate of the first compound and another compound making up the gas stream (such as combination of SF₆ and H₂) under current standard conditions as defined by the International Union of Pure and Applied Chemistry. In some embodiments, the flow rate ratio was measured under a pressure of 100 mTorr, and an advantageous flow rate ratio was observed to be below 0.3.

Removal of molybdenum-comprising material from the substrate, or from another surface, depending on the application, takes place when oxygen reactant is provided into the reaction chamber. The reactive oxygen species contained in the plasma react with the halogenated molybdenum-comprising surface and form volatile molybdenum compound which will leave the surface in question. In some embodiments, the volatile molybdenum compound comprises molybdenum, oxygen and a halogen, such as fluorine. In some embodiments, the volatile molybdenum compound consists of molybdenum, oxygen and a halogen, such as fluorine. In some embodiments, the volatile molybdenum compound is MoF₂O₂.

Thus, the oxygen reactant oxidizes the halogenated compounds on the surface, the oxidized species is the volatile molybdenum compound, and the process results in removal of material from the substrate surface. In some embodiments, the oxygen reactant is an oxygen-comprising plasma generated from a gas comprising an oxygen source selected from a group consisting of CO₂, N₂O, H₂O and O₂. In some embodiments, the oxygen reactant is an oxygen-comprising plasma generated from a gas comprising an oxygen source selected from a group consisting of CO₂, N₂O, H₂O and O₂ or a combination thereof. In some embodiments, the oxygen comprising plasma is generated from a gas comprising CO₂. In some embodiments, the oxygen reactant is plasma generated from a gas comprising CO₂ as the only oxygen source. In some embodiments, the oxygen comprising plasma is generated from a gas comprising N₂O. In some embodiments, the oxygen reactant is plasma generated from a gas comprising N₂O as the only oxygen source. In some embodiments, the oxygen reactant is plasma generated from a gas comprising H₂O. In some embodiments, the oxygen reactant is plasma generated from a gas comprising H₂O as the only oxygen source. In some embodiments, the oxygen reactant is plasma generated from a gas comprising O₂. In some embodiments, the oxygen reactant is plasma generated from a gas comprising O₂ as the only oxygen source. In some embodiments, the oxygen reactant is plasma generated from a gas consisting essentially of, or consisting of, O₂. In some embodiments, the oxygen reactant is a plasma generated from a gas comprising more than one oxygen source, such as O₂ and H₂O, O₂ and N₂O, or O₂ and CO₂, or CO₂ and N₂O.

In some embodiments, the oxygen reactant is ozone (O₃). In embodiments, in which O₃ is used as the oxygen reactant, the reaction chamber conditions, such as temperature and pressure may be different than in embodiments, in which the oxygen reactant is plasma. The selection of a thermal or plasma-based oxygenation in the process may depend on the properties of the molybdenum-comprising material. For example, for removing crystalline, such as polycrystalline, molybdenum-comprising material, oxygen-comprising plasma may be more advantageous than thermal methods6, such as methods using O₃ in the process. On the other hand, O₃ may be preferred in embodiments, in which the substrate comprises materials that are sensitive to plasma. An O₃-based process may be used to avoid damage caused by plasma to such surfaces.

In some embodiments, the method according to the current disclosure is a cyclic process. Generally, in cyclic processes, such as atomic layer etching (ALEt), a first reactant (such as halogen-comprising plasma) is introduced to a reaction chamber and is chemisorbed to a substrate surface (e.g., a substrate surface that may include a deposited material or other material), leading to a modified surface. Typically, the first reactant on the substrate surface does not readily react with additional reactant, or etch the surface (i.e., the modification of the substrate surface is a partially or fully self-limiting reaction). Thereafter, a second reactant (such as oxygen reactant) may be introduced into the reaction chamber for use in converting the modified surface material to one or more volatile species that leaves the surface. As the volatile species leaves the surface, the thickness of the original material is reduced, approximately to the depth of the original modification by the first reactant. This leads to a well-controlled material removal (such as etching or cleaning). Purging steps may be utilized during one or more cycles, e.g., during each step of each cycle, to remove any excess reactant and/or reaction byproducts from the reaction chamber. Thus, in some embodiments, the cyclic process comprises purging the reaction chamber after providing a reactant into the reaction chamber. In some embodiments, the cyclic process comprises purging the reaction chamber after providing a first reactant (in this disclosure, halogen-comprising plasma) into the reaction chamber. In some embodiments, the cyclic process comprises purging the reaction chamber after providing a second reactant (in this disclosure, oxygen reactant) into the reaction chamber. In some embodiments, the cyclic process comprises purging the reaction chamber after providing a first reactant into the reaction chamber, and after providing a second reactant into the reaction.

The method according to the current disclosure may comprise one or more cyclic phases. In some embodiments, the process comprises one or more acyclic (i.e. continuous) phases. In some embodiments, the method comprises the continuous flow of at least one reactant. In such an embodiment, the process comprises a continuous flow of a first reactant or a second reactant. In some embodiments, one or more of the reactants are provided in the reaction chamber continuously.

In some embodiments, the method is a cyclic material removal method, and providing the halogen-comprising plasma in the reaction chamber and providing an oxygen reactant into the reaction chamber form a material removal cycle. In some embodiments, the material removal cycle is performed at least twice. In some embodiments, the halogen-comprising plasma and the oxygen reactant are provided into the reaction chamber alternately and sequentially. In such embodiments, each reactant plasma is provided into the reaction chamber in discrete pulses. In some embodiments, at least one of halogen-comprising plasma (such as a sulfur and halogen-comprising plasma) and oxygen reactant is provided to the reaction chamber in pulses. In some embodiments, the halogen-comprising plasma is supplied in pulses and the oxygen reactant is supplied in pulses, and the reaction chamber is purged between consecutive pulses of halogen-comprising plasma and oxygen reactant. A duration of providing halogen-comprising plasma and/or oxygen reactant into the reaction chamber (i.e. halogen-comprising plasma pulse time and oxygen reactant pulse time, respectively) may be, for example, from about 0.01 seconds(s) to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The duration of halogen-comprising plasma or an oxygen reactant pulse may be, for example 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, the halogen-comprising plasma is provided into the reaction chamber from about 0.1 s to about 20 s. In some embodiments, the oxygen reactant is provided into the reaction chamber from about 0.1 s to about 20 s. In some embodiments, the halogen-comprising plasma is provided into the reaction chamber for about 5 to 10 s, such as 6 s, 7 s or 8 s, and the oxygen reactant is provided into the reaction chamber for about 3 s to 7 s, such as 4 s, 5 s, or 6 s.

In some embodiments, halogen-comprising plasma pulse time may be at least 5 s, or at least 10 s. In some embodiments, halogen-comprising plasma pulse time may be at most 5 s, or at most 10 s or at most 20 s, or at most 30 s. In some embodiments, oxygen reactant pulse time may be at least 5 s, or at least 10 s, or at least 20 s. In some embodiments, oxygen reactant pulse time may be at most 5 s, or at most 10 s or at most 20 s, or at most 30 s.

In some embodiments, the removal of molybdenum-comprising material is substantially self-limiting. In other words, extending pulse duration of either halogen-comprising plasma or oxygen reactant does not substantially increase the rate at which the molybdenum-comprising material is removed per removal cycle. The advantages of the methods according to the current disclosure may be evident also in the absence of fully self-limiting behavior of the process. However, the more self-limiting the process, the better the control over it is. Therefore, it may be advantageous to optimize the process conditions to achieve as self-limiting behavior as possible.

The pulse times for halogen-comprising plasma, and for oxygen reactant vary independently according to process in question. The selection of an appropriate pulse time may depend on the substrate topology. For higher aspect ratio structures, longer pulse times may be needed to obtain sufficient surface saturation in different areas of a high aspect ratio structure. Also the selected first reactant and second reactant chemistries may influence suitable pulsing times. For process optimization purposes, shorter pulse times might be preferred as long as appropriate layer properties can be achieved. In some embodiments, halogen-comprising plasma pulse time is longer than oxygen reactant pulse time. In some embodiments, oxygen reactant pulse time is longer than halogen-comprising plasma pulse time. In some embodiments, halogen-comprising plasma pulse time is the same as oxygen reactant pulse time.

In some embodiments, providing halogen-comprising plasma and/or an oxygen reactant into the reaction chamber comprises pulsing the halogen-comprising plasma and the oxygen reactant over a substrate. In certain embodiments, pulse times in the range of several minutes may be used for the halogen-comprising plasma and/or the oxygen reactant. In some embodiments, halogen-comprising plasma may be pulsed more than one time, for example two, three or four times, before an oxygen reactant is pulsed to the reaction chamber. Similarly, there may be more than one pulse, such as two, three or four pulses of an oxygen reactant before halogen-comprising plasma is pulsed (i.e. provided) into the reaction chamber.

In some embodiments, the reaction chamber is purged between plasma pulses. As used herein, the term “purge” refers to a procedure in which vapor phase reactants and/or byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases or plasmas which react with each other. However, purging may be effected between two pulses of gases that do not react with each other. Purging may avoid or at least reduce gas-phase interactions between vapor-phase compounds reacting with each other. It shall be understood that a purge can be effected either in time or in space, or both. For example, in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first reactant (such as a sulfur and halogen-comprising plasma) is continually supplied, through a purge gas curtain or another means of separating the two spaces, to a second location to which a second reactant (such as an oxygen reactant) is continually supplied. Purging times may be, for example, from about 0.01 s to about 20 s, from about 0.05 s to about 20 s, or from about 1 s to about 20 s, or from about 0.5 s to about 10 s, or between about 1 s and about 7 s, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

In some embodiments, the method according to the current disclosure comprises providing a conversion reactant into the reaction chamber after providing the oxygen reactant to modify an exposed surface of the substrate. In some embodiments, the conversion reactant is provided as or in plasma. In some embodiments, the conversion reactant is provided in a vapor phase. The exposed surface to be modified may comprise the molybdenum-comprising material. In some embodiments, the exposed to be modified comprises a material from which molybdenum-comprising material has been removed. The conversion reactant may be provided as a pulse. The conversion reactant may be provided once after providing the oxygen reactant into the reaction chamber. In embodiments, in which the process is a cyclic process, the conversion reactant may be provided after the last material removal cycle. In some embodiments, the conversion reactant comprises a reducing agent. In some embodiments, the reducing agent is used to reduce remaining molybdenum oxide into elemental molybdenum. In some embodiments, the conversion reactant is used to convert molybdenum oxide into MoS₂. In such embodiments, the conversion reactant comprises, consists essentially of, or consists of, H₂S. In some embodiments, the conversion reactant is used to convert molybdenum oxide into molybdenum nitride. In such embodiments, the conversion reactant comprises, consists essentially of, or consists of, NH₃.

The process may comprise one or more cyclic phases. In some embodiments, the process comprises or one or more acyclic (i.e. continuous) phases. In some embodiments, the deposition process comprises the continuous flow of at least one precursor. In such an embodiment, the process comprises a continuous flow of a first polymer precursor or second polymer precursor. In some embodiments, one or more of the precursors are provided in the reaction chamber continuously.

In some embodiments, the method according to the current disclosure is used to selectively remove out-of-plane MoS₂ defects (i.e. out-of-plane oriented structures, “fins”) from deposited MoS₂. Out-of-plane defects are vertical growth areas of a crystalline MoS₂ plane. The MoS₂ may be deposited using atomic layer deposition (ALD), with the possibility of producing very thin layers. Generally, in ALD, during each cycle, a precursor is introduced to a reaction chamber and is chemisorbed to a substrate surface (e.g., a substrate surface that may include a previously deposited material from a previous deposition cycle or other material). The precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor.

In some embodiments, the removal rate of the molybdenum-comprising material is less than about 1.2 Å/cycle. In some embodiments, the etching rate of the molybdenum-comprising material is less than about 1.1 Å/cycle, or less than about 1.0 Å/cycle, less than about 0.8 Å/cycle, or less than about 0.7 Å/cycle, or less than about 0.5 Å/cycle, or less than about 0.3 Å/cycle. In some embodiments, the etching rate of the molybdenum-comprising material is from about 0.05 to about 1.2 Å/cycle, or from about 0.1 to about 1.2 Å/cycle, or from about 0.1 to about 1.0 Å/cycle, or from about 0.1 to about 0.7 Å/cycle, or from about 0.1 to about 0.5 Å/cycle, or from about 0.05 to about 0.2 Å/cycle, or from about 0.05 to about 3 Å/cycle, or from about 0.05 to about 0.5 Å/cycle. The removal rate of the molybdenum-comprising material can be influenced particularly by the pulse time of the halogen-comprising plasma, and partial pressures of the gases used to generate the plasmas, as well as power used to generate the plasma. In some embodiments, the method according to the current disclosure is a cyclic material removal (such as etching) method, and between 1 and about 10 monolayers of molybdenum-comprising material are etched in one material removal cycle.

In some embodiments, a plasma used in the current disclosure is a direct capacitively coupled plasma. In some embodiments, a plasma used in the current disclosure is radio frequency (RF) generated plasma. The plasma can be one of a remote plasma, an indirect plasma, and a direct plasma. In some embodiments, a plasma according to the current disclosure is generated directly above the substrate. In other words, the plasma is direct plasma. A direct plasma may be generated between a showerhead injector and the substrate. In some embodiments, a plasma is generated away from the substrate. In other words, the plasma is a remote plasma. In some embodiments, a remote plasma generator is used for generating a plasma.

The power of the plasma generator may be, from about 50 W to about 500 W, such as from about 50 W to about 200 W, or from about 75 W to about 250 W. In some embodiments, the plasma power is about 75 W, about 100 W, about 150 W, about 200 W, or about 300 W. In some embodiments, radio frequency may be used to generate one or both plasmas used in the method according to the current disclosure.

In some embodiments, the method according to the current disclosure is performed at a temperature of at least about 100° C. to at most about 600° C., or at a temperature of at least about 300° C. to at most about 500° C., or at a temperature of at least about 300° C. to at most about 400° C., or at a temperature of about 350° C. The temperature at which the method is performed may be the temperature at which the substrate is maintained.

In one aspect, a method of cleaning a surface is disclosed. The method of cleaning a surface comprises providing a surface having molybdenum-comprising material thereon, contacting the surface with a halogen-comprising plasma to halogenate the molybdenum-comprising material, and contacting the surface with an oxygen reactant to form a volatile molybdenum compound.

In another aspect, a method of removing oxidized material from an elemental molybdenum layer is disclosed. The method comprises providing an elemental molybdenum layer having oxidized material thereon, contacting the elemental molybdenum layer with a halogen-comprising plasma to halogenate the oxidized material, and contacting the elemental molybdenum layer with an oxygen reactant to form a volatile molybdenum compound.

In some embodiments, the method of removing oxidized material is performed in a reaction chamber.

In yet another aspect, a method of thinning a molybdenum nitride layer is disclosed. The method comprises providing a substrate comprising a molybdenum nitride layer in a reaction chamber, providing a halogen-comprising plasma in the reaction chamber to halogenate the molybdenum nitride layer, and providing an oxygen reactant into the reaction chamber to form a volatile molybdenum compound.

In further aspect, a work function layer consisting essentially of molybdenum nitride formed by a method according to the current disclosure is disclosed.

In an additional aspect, a semiconductor processing assembly is disclosed. The semiconductor processing assembly comprises a reaction chamber constructed and arranged to hold a substrate comprising a molybdenum-comprising layer and an injector system constructed and arranged to provide a halogen-comprising plasma and an oxygen reactant into the reaction chamber. The semiconductor processing assembly further comprises a halogen reactant source constructed and arranged to contain a halogen reactant for generating a halogen-comprising plasma and an oxygen reactant source constructed and arranged to contain an oxygen reactant for generating the oxygen reactant. The semiconductor processing assembly is constructed and arranged to provide the halogen-comprising plasma and the oxygen reactant via the injector system into the reaction chamber to remove molybdenum-comprising material from the substrate.

In some embodiments of the semiconductor processing assembly, the injector system comprises a plasma generator located upstream of the reaction chamber.

In some embodiments of the semiconductor processing assembly, the injector system comprises a plasma generator for generating plasma in the reaction chamber.

In some embodiments of the semiconductor processing assembly, the assembly comprises a controller configured to cause the semiconductor processing assembly to provide the halogen-comprising plasma and the oxygen reactant alternately and sequentially into the reaction chamber.

In a yet further aspect, a semiconductor processing assembly constructed and arranged to perform a method according to the current disclosure is disclosed.

### BRIEF DESCRIPTION OF DRAWINGS

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

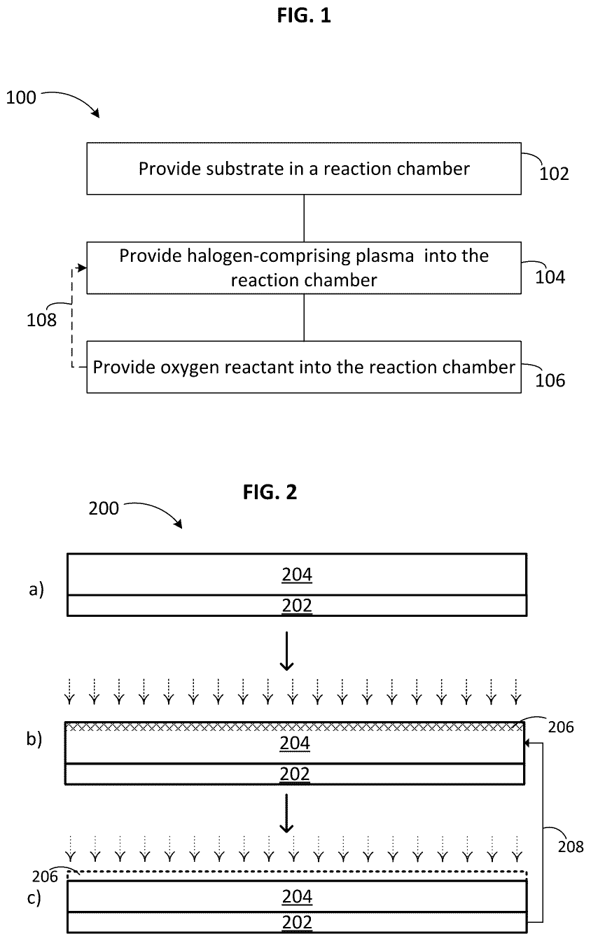

FIG. 1 illustrates an example diagram of a method according to the disclosure current;

FIG. 2 is an illustrate schematic presentation of a method 200 according to the current disclosure

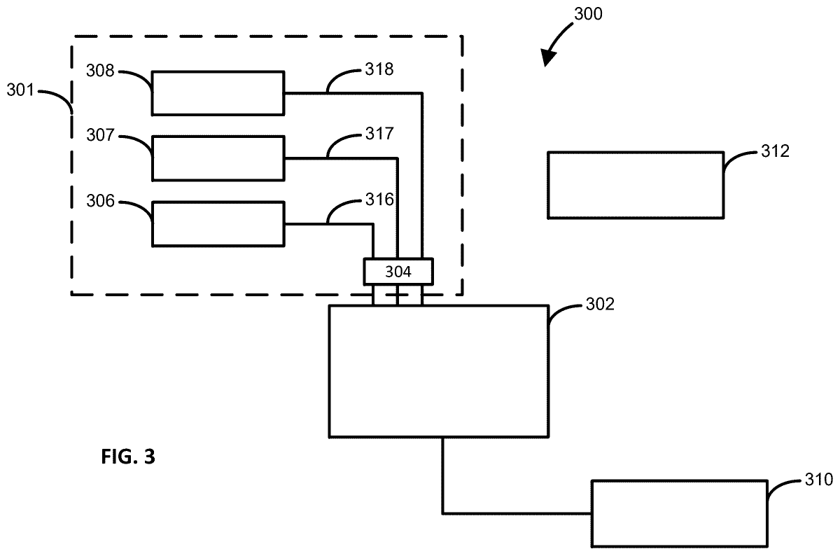

FIG. 3 illustrates a semiconductor processing assembly according to the current disclosure.

### DETAILED DESCRIPTION

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. M any alternative or additional functional relationship or physical connections may be present in the practical system, and/or may be absent in some embodiments.

FIG. 1 illustrates exemplary embodiments of a method according to the current disclosure as a block diagram. Method 100 may be used to remove molybdenum-comprising material from a substrate. In some embodiments, molybdenum-comprising material can be removed from other surfaces, but for simplicity, a removal method performed on a substrate is described in detail. In some embodiments, the method according to the current disclosure is an etching method. In some embodiments, the method can be an atomic layer etching method. In some embodiments, the method may be a cleaning method, such as a pre-cleaning method. The method 100 can be used during a formation of a semiconductor structure or device.

During step 102, a substrate is provided into a reaction chamber of a substrate processing apparatus, such as a reaction chamber of a semiconductor processing assembly. The reaction chamber can form part of cluster tool. In some embodiments, the substrate processing apparatus is a single-wafer processing apparatus. Alternatively, the apparatus may be a batch processing apparatus. The method 100 can be performed within a single reaction chamber or, depending on the number of phases in the process, in multiple reaction chambers, such as reaction chambers of a cluster tool. In some embodiments, the substrate may be moved between treatment stations of a multi-station processing chamber. Such embodiments may have advantages in methods comprising both etching and deposition processes. In some embodiments, the method 100 is performed in a single reaction chamber of a cluster tool, but other, preceding or subsequent, manufacturing steps of the structure or device are performed in additional reaction chambers of the same cluster tool. The reaction chamber can be provided with a heater to activate the reactions by elevating the temperature of one or more of the substrate and/or the reactants and/or other gases.

During step 102, the substrate can be brought to a desired temperature and pressure for providing a halogen-comprising plasma into the reaction chamber (block 104) and for providing an oxygen reactant into the reaction chamber (block 106), if they are performed in the same temperature. A temperature (e.g. of a substrate or a substrate support) within a reaction chamber can be, for example, from about 20° C. to about 600° C., from about 20° C. to about 500° C., from about 20° C. to about 450° C., from about 20° C. to about 350° C. or from about 20° C. to about 300° C. or from about 20° C. to about 200° C. or from about 20° C. to about 100° C. As a further example, a temperature within a reaction chamber can be from about 100° C. to about 350° C., or from about 100° C. to about 200° C., or from about 200° C. to about 350° C., or from about 250° C. to about 500° C. Exemplary temperatures within the reaction chamber may be 25° C., 50° C., 100° C., 170° C., 190° C., 250° C., 300° C., 330° C., or 380° C.

In some embodiments, providing a halogen-comprising plasma into the reaction chamber (block 104) and providing an oxygen reactant into the reaction chamber (block 106) are performed in different temperatures. The temperatures of each of blocks 104 and 106 can be selected independently according to the particular process conditions and chemistries.

A pressure within the reaction chamber can be less than 760 Torr, for example less than 100 Torr, less than 50 Torr, less than 20 Torr, less than 5 Torr, less than 1 Torr or less than 0.5 Torr. In some embodiments, a pressure within the reaction chamber is from about 0.01 Torr to about 50 Torr, or from about 0.01 Torr to about 10 Torr, or from about 0.01 Torr to about 5 Torr, or from about 0.01 Torr to about 1 Torr, or from about 0.01 Torr to about 0.5 Torr, or from about 0.01 Torr to about 0.1 Torr. Exemplary reaction chamber pressures include about 50 mTorr, about 100 mTorr, about 500 mTorr, about 800 mTorr, about 1 Torr or about 3 Torr. Different pressure may be used for different process steps. In some embodiments, the pressure is the same throughout the process.

At block 104, halogen-comprising plasma is provided into the reaction chamber to remove material from the substrate surface. The duration of providing a halogen-comprising plasma into the reaction chamber 104 (halogen-comprising plasma pulse time) may be, for example, from about 0.1 seconds to about 10 minutes. The halogen-comprising plasma pulse time 104 is selected based on the reactivity of the halogen-comprising plasma and other process conditions, such as temperature. In some embodiments, halogen-comprising plasma pulse time is from about 0.5 seconds to about 3 minutes, or from about 0.5 seconds to about 1 minute, or from about 0.5 seconds to about 45 seconds, or from about 0.5 seconds to about 30 seconds. In some embodiments, halogen-comprising plasma pulse time is from about 1 second to about 3 minutes, or from about 1 second to about 1 minute, or from about 4 seconds to about 60 seconds, or from about 5 seconds to about 60 seconds. In some embodiments, the halogen-comprising plasma pulse time is longer than 1 second or longer than 5 seconds. In some embodiments, the halogen-comprising plasma pulse time is shorter than about 3 minutes or shorter than about 1 minute or shorter than about 40 seconds, or shorter than about 30 second, or shorter than about 20 seconds, or shorter than about 10 seconds, or shorter than about 5 seconds.

At block 106, oxygen reactant is provided in the reaction chamber. As discussed above, the oxygen reactant may be provided into the reaction chamber in thermal mode or in plasma mode. In thermal mode, the phase of providing an oxygen reactant into the reaction chamber does not comprise plasma. In such embodiments, the oxygen reactant can be, for example, ozone. In plasma mode, the phase of providing an oxygen reactant into the reaction chamber comprises providing an oxygen-comprising plasma into the reaction chamber the oxygen reactant may be an oxygen-comprising plasma that is generated from an oxygen-comprising gas. Examples of the oxygen reactant being an oxygen-comprising plasma are plasmas generated from gases comprising CO₂, N₂O or O₂. In some embodiments, the oxygen reactant is plasma generated from a gas comprising O₂.

FIG. 2 is a schematic presentation of a method 200 according to the current disclosure.

Panel a) depicts a substrate 202 comprising molybdenum-comprising material 204 thereon. In the example of FIG. 2, the molybdenum-comprising material 204 is positioned on bulk substrate material 202, but the underlying material may be other material, such as previously deposited device structures. Additionally, although the molybdenum-comprising material 204 is depicted as being in one plane in FIG. 2, the surface of the molybdenum-comprising material 204 may be on different vertical levels, and/or have variable topologies. Further, the surface of the substrate may comprise additional materials in addition to the molybdenum-comprising material that may or may not be susceptible to material removal according to the current disclosure. Further, the substrate may comprise patterning and/or one or more masks, such as hard masks, to prevent certain areas from being exposed to the treatments of the current methods. The areas of the substrate covered by a mask material may be molybdenum-comprising material or another material.

In a non-limiting example, the molybdenum-comprising material 204 consists substantially of MoS₂, and the method according to the current disclosure is performed at a temperature of 300° C. The temperature may be indicated as the susceptor temperature.

Panel b) illustrates providing a halogen-comprising plasma (dashed arrows) into the reaction chamber to halogenate the molybdenum-comprising material 204. The halogenated, such as fluorinated, surface of the molybdenum-comprising material 204 is indicated by the cross-hatching 206. In an exemplary embodiment, the halogen-comprising plasma is plasma generated from SF₆-comprising gas. The gas used for plasma generation further comprises molecular hydrogen. The gas used for plasma generation may comprise additional compounds or elements. For example, the gas used for plasma generation may comprise a noble gas, such as argon. Further, additional gases may be provided into the chamber, without passing them through plasma generation. In an exemplary embodiment, the molybdenum-comprising material is exposed to plasma generated from a gas comprising SF₆, H₂ and Ar. The surface of the molybdenum-comprising material becomes halogenated, and it may comprise halogen terminations, such as halogen and hydrogen-containing terminations or halogen and chalcogen-containing terminations, for example —SF terminations. In some embodiments, substantially only the surface-most molecular layer becomes halogenated.

Panel c) illustrates providing an oxygen reactant (dotted arrows) into the reaction chamber. As described above, the oxygen reactant may be oxygen-comprising plasma or a reactive oxygen compound, such as ozone, capable of oxidizing the halogenated species on the surface of the halogenated molybdenum-comprising material. In exemplary embodiments, the oxygen reactant is plasma generated from O₂-comprising gas. Alternatively, alternative oxygen-comprising gases, such as CO₂, N₂O, H₂O and O₂ can be used for generating the oxygen-comprising plasma. As depicted in the drawing, the halogenated molybdenum-comprising material 206 is removed from the substrate during providing the oxygen reactant into the reaction chamber.

In some embodiments, the method according to the current disclosure is a cyclic etching method, such as atomic layer etching method. In such embodiments, the removal (such as etching) of molybdenum-comprising material is limited to the halogenated material, and the material removal is substantially self-limiting. In other words, increasing the halogen-comprising plasma pulse time and/or the oxygen reactant pulse time does not lead to substantially higher rate of molybdenum-comprising material removal per cycle. In some embodiments, the methods according to the current disclosure are partially self-limiting.

The cycle 208 of FIG. 2 indicates a cyclic process, in which each material removal cycle comprises a halogen-comprising plasma pulse (panel b)) and an oxygen reactant pulse (panel c)). The process according to the current disclosure may contain two or more material removal cycles, such as from 2 to about 500, or from 2 to about 100 or from 2 to about 50 or from 2 to about 10 or from about 5 to about 100 or from about 5 to about 200 material removal cycles. The number of material removal cycles depends on the material removal rate per cycle as well as from the desired amount of material being removed per cycle.

In embodiments in which the oxygen reactant is oxygen-comprising plasma, the plasma can be generated by the same plasma generator having the same power. For example, the plasma may be inductively coupled plasma (ICP) generated by a plasma generator with 80 to 200 W power, such as 100 W or 150 W.

FIG. 3 illustrates a semiconductor processing assembly 300 according to the current disclosure in a schematic form. As a schematic representation of a semiconductor processing assembly 300, many components have been omitted for simplicity of illustration, and such components may include, for example, various valves, manifolds, purifiers, heaters, containers, vents, and/or bypasses.

The semiconductor processing assembly 300 may comprise a reaction chamber 302 constructed and arranged to hold a substrate comprising a molybdenum-comprising layer. The semiconductor processing assembly 300 further comprises a plasma generator 304 for generating halogen-comprising plasma and optionally oxygen-comprising plasma, a halogen reactant source 306 and a hydrogen source 307 for providing halogen-comprising gas and hydrogen-comprising gas, respectively, to generate halogen-comprising plasma by the plasma generator 304. The halogen reactant source 306 is constructed and arranged to contain a halogen reactant, such as SF₆ for generating a halogen-comprising plasma. The semiconductor processing assembly 300 further comprises an oxygen reactant source 308 constructed and arranged to contain an oxygen reactant. In embodiments, in which the oxygen reactant is an oxygen-comprising plasma, the oxygen reactant from the oxygen reactant source 308 is used for generating the oxygen-comprising plasma. The oxygen reactant, in thermal or plasma mode, is provided into the reaction chamber 302.

The sources 306, 307 and 308 are connected by gas lines 316, 317 and 318, respectively, to the reaction chamber 302 for providing a fluid communication path from the sources 306, 307 and 308 to the reaction chamber 302. In the embodiment of FIG. 3, the plasma generator 304 is a remote plasma unit located upstream of the reaction chamber 302. The sources 306 and 307 are connected to the reaction chamber 302 through the plasma generator 304. Although the gas lines 316 and 317 are drawn separately in FIG. 3, they may be connected at some point upstream of the plasma generator 304. As is known to those skilled in the art, the gas flows in the semiconductor processing assembly 300 are carefully regulated, and the gas lines and sources therefore may contain various valves and other flow regulators.

In the depicted embodiment, also the gas line 318 from the oxygen reactant source 308 connects to the reaction chamber 302 through the plasma generator 304. Thus, in the embodiment of FIG. 3, the oxygen reactant is an oxygen-comprising plasma. The gas lines 316, 317 and 318 together with the plasma generator 304 and all the supporting equipment, such as valves, manifolds, heaters, electrical components etc. form an injector system 301 constructed and arranged to provide a halogen-comprising plasma and an oxygen reactant into the reaction chamber. The semiconductor processing assembly 300 is thus constructed and arranged to provide the halogen-comprising plasma and the oxygen reactant via the injector system 301 into the reaction chamber 302 to remove molybdenum-comprising material from the substrate. The semiconductor processing assembly may further comprise additional gas sources, and corresponding gas lines, valves, etc. to provide purge gases or other process gases into the reaction chamber 302.

FIG. 3 additionally illustrates an exhaust gas source 310. An exhaust source 310 may comprise one or more vacuum pumps. The embodiment of a semiconductor processing assembly 300 additionally comprises a controller 312. The controller 312 includes electronic circuitry and software to selectively operate valves, manifolds, heaters, pumps and other components included in the semiconductor processing assembly 300. Such circuitry and components operate to provide gases, regulate temperature, pressure etc. to provide proper operation of the semiconductor processing assembly 300. Controller 312 can include modules such as a software or hardware component, which performs certain tasks.

The semiconductor processing assembly of FIG. 3 may be a part of a cluster tool comprising multiple reaction chambers 302. The reaction chamber 302 may be an individual processing station of a multi-station chamber. In some embodiments, the semiconductor processing assembly 300 comprises a hot-wall, cold-wall or warm-wall type of reaction chamber 302.

During operation of semiconductor processing assembly 300, substrates, such as semiconductor wafers (not illustrated), are transferred from, e.g., a substrate handling system to reaction chamber 302. Once substrate(s) are transferred to reaction chamber 302, one or more gases from gas sources 306, 307 and 308, such as for generating plasma and/or purge gases, are introduced into reaction chamber 302.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of removing molybdenum-comprising material from a surface of a substrate, the method comprising
providing a substrate comprising molybdenum-comprising material in a reaction chamber;
providing a halogen-comprising plasma in the reaction chamber to halogenate the molybdenum-comprising material; and
providing an oxygen reactant into the reaction chamber to form a volatile molybdenum compound.

2. The method of claim 1, wherein the halogen-comprising plasma further comprises sulfur.

3. The method of claim 1, wherein the oxygen reactant is an oxygen-comprising plasma.

4. The method of claim 1, wherein the halogen-comprising plasma and the oxygen reactant are provided into the reaction chamber alternately and sequentially.

5. The method of claim 1, wherein the molybdenum-comprising material is selected from a group consisting of molybdenum dichalcogenides, molybdenum nitride, molybdenum oxide, molybdenum carbide, metallic molybdenum and combinations thereof.

6. The method of claim 5, wherein the molybdenum-comprising material is selected from a group consisting of MoS₂, MoSe₂ and combinations thereof.

7. The method of claim 1, wherein the halogen-comprising plasma is generated from a gas comprising SF₆.

8. The method of claim 1, wherein the halogen-comprising plasma is generated from a gas comprising molecular hydrogen (H₂).

9. The method of claim 7, wherein the halogen-comprising plasma is generated from a gas comprising molecular hydrogen (H₂), and a flow rate ratio of SF₆ to a combination of SF₆ and H₂ is below 0.9.

10. The method of claim 1, wherein the oxygen reactant is an oxygen-comprising plasma generated from a gas comprising an oxygen source selected from a group consisting of CO₂, N₂O, H₂O and O₂.

11. The method of claim 1, wherein the method is a cyclic material removal method, and providing the halogen-comprising plasma in the reaction chamber and providing an oxygen reactant into the reaction chamber form a material removal cycle.

12. The method of claim 11, wherein the material removal cycle is performed at least twice.

13. The method of claim 11, wherein a removal rate of the molybdenum-comprising material is less than about 1.2 Å/cycle.

14. The method of claim 11, wherein the halogen-comprising plasma is provided into the reaction chamber from about 0.1 seconds to about 20 seconds.

15. The method of claim 9, wherein the oxygen reactant is provided into the reaction chamber from about 0.1 seconds to about 20 seconds.

16. The method of claim 1, wherein removal of molybdenum-comprising material is substantially self-limiting.

17. A method of cleaning a surface, the method comprising
providing a surface having molybdenum-comprising material thereon;
contacting the surface with a halogen-comprising plasma to halogenate the molybdenum-comprising material; and
contacting the surface with an oxygen reactant to form a volatile molybdenum compound.

18. A method of removing oxidized material from an elemental molybdenum layer, the method comprising
providing an elemental molybdenum layer having oxidized material thereon;
contacting the elemental molybdenum layer with a halogen-comprising plasma to halogenate the oxidized material; and
contacting the elemental molybdenum layer with an oxygen reactant to form a volatile molybdenum compound.

19. The method of claim 16, wherein the method is performed in a reaction chamber.

20. A method of thinning a molybdenum nitride layer, the method comprising
providing a substrate comprising a molybdenum nitride layer in a reaction chamber;
providing a halogen-comprising plasma in the reaction chamber to halogenate the molybdenum nitride layer; and
providing an oxygen reactant into the reaction chamber to form a volatile molybdenum compound.

21. A work function layer consisting essentially of molybdenum nitride formed by a method according to claim 18.

22. A semiconductor processing assembly comprising
a reaction chamber constructed and arranged to hold a substrate comprising a molybdenum-comprising layer;
an injector system constructed and arranged to provide a halogen-comprising plasma and an oxygen reactant into the reaction chamber;
wherein the semiconductor processing assembly further comprises
a halogen reactant source constructed and arranged to contain a halogen reactant for generating a halogen-comprising plasma and
an oxygen reactant source constructed and arranged to contain an oxygen reactant; and
the semiconductor processing assembly is constructed and arranged to provide the halogen-comprising plasma and the oxygen reactant via the injector system into the reaction chamber to remove molybdenum-comprising material from the substrate.

23. The semiconductor processing assembly of claim 22, wherein the injector system comprises a plasma generator located upstream of the reaction chamber.

24. The semiconductor processing assembly of claim 22, wherein the injector system comprises a plasma generator for generating plasma in the reaction chamber.

25. The semiconductor processing assembly of claim 22, comprising a controller configured to cause the semiconductor processing assembly to provide the halogen-comprising plasma and the oxygen reactant alternately and sequentially into the reaction chamber.

26. A semiconductor processing assembly constructed and arranged to perform a method according to claim 1.
